(19) United States
(12) Patent Application Publication
(10) Pub. No.: US 2005/0221620 A1
(43) Pub. Date: Oct. 6, 2005

(54) Process for etching a substrate

(76) Inventors: Teng-Wang Huang, Dresden (DE); Kristin Schupke, Dresden (DE)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 10/814,570

(22) Filed: Mar. 31, 2004

(51) Int. Cl. H01L 21/302

(52) U.S. Cl. 438/745; 438/749; 438/753

(57) ABSTRACT

The invention relates to a process for etching at least one substrate, in particular at least one silicon wafer for the fabrication of DRAM memory chips. The process comprising at least one substrate, for a first etching step, is arranged for a predetermined time in a first vessel containing a first etchant, then at least one substrate, for a first rinsing step, is arranged for a predetermined time in a second vessel containing a first rinsing agent, the first rinsing agent containing at least one wetting agent, and then at least one substrate, for a second etching step, is arranged for a predetermined time in a third vessel containing a second etchant.

The invention relates to a process in accordance with the preamble of claim 1.

In the context of the fabrication of semiconductor components, e.g. DRAM memory chips, the object is set of introducing very fine structures into a substrate, such as for example a silicon wafer. Inter alia, etching techniques are used for this purpose, in which layers of the substrate are removed over the entire surface or masked patterns produced by lithography are transferred into the layer below.

One technique which is frequently used in this context is wet-etching, in which the material removed from the substrate is converted into a soluble compound. Dilute hydrofluoric acid (HF) is often used as etchant for silicon wafers. The wet etching is carried out either by means of spray etching or by means of dip etching, with the substrates passing through complex sequences of etching, rinsing and drying steps.

In the context of the fabrication of DRAM memory chips, it is known to subject silicon wafers to a series of process steps in a tank in order to produce structures with high aspect ratios (ratio of the depth or height of the structure to the width of the structure). For example, in the case of what are known as deep trenches for DRAMs, aspect ratios of 50 and above are possible. Wet-chemical process sequences which have an effect on such aspect ratios are, in a known way, in what is known as a point-of-use tank, in which silicon wafers are successively subjected to a first etching step using dilute hydrofluoric acid, a first rinsing step, a second etching step using NH₄OH and a second rinsing step. The silicon wafers are then dried.

The first etching step is used to remove a native oxide layer from the surface of the silicon wafer. The second etching step serves to increase the feature size (widening, fabrication of a bottle structure).

However, if it is desired to transfer these process steps to a bench tool, in which the process steps are carried out sequentially in different tanks, a problem arises on account of the need to transport the silicon wafers between the tanks. After the first etching step using the dilute hydrofluoric acid, the surface of the silicon wafer is hydrophobic, and consequently after the first rinsing step the NH₄OH solution does not make sufficient contact with the silicon surface, and consequently the result of the second etching step is inadequate.

The present invention is based on the object of providing a process which avoids these problems.

According to the invention, this object is achieved by a process having the features of claim 1.

This involves passing through the following steps:

a) at least one substrate, for a first etching step, is arranged for a predetermined time in a first vessel containing a first etchant, then

b) at least one substrate, for a first rinsing step, is arranged for a predetermined time in a second vessel containing a first rinsing agent, the first rinsing agent containing at least one wetting agent, and then

c) at least one substrate, for a second etching step is arranged for a predetermined time in a third vessel containing a second etchant.

The use of the wetting agent in the first rinsing step allows the subsequent second etch to be carried out more successfully.

It is then advantageous if at least one substrate, after the second etching step, is subjected to a second rinsing step using a second rinsing agent in a fourth vessel. At least one substrate is advantageously subjected to a drying step after the second rinsing step.

It is advantageous for the first etchant to include a hydrofluoric acid fraction. It is also advantageous if the second etchant includes an ammonia hydroxide (NH₄OH) fraction. In one particularly advantageous embodiment, the first rinsing agent contains the wetting agent in a concentration in the range from 0.01 to 0.1% by weight.

It is advantageous for at least one structure with an aspect ratio in the range from 10 to 80 to be offered up in the second etching step in order for the feature size to be enlarged. In this context, it is particularly advantageous if the structure is a deep trench structure for a DRAM memory cell. The surface treatment of structures with a large aspect ratio is particularly important, since the long, narrow spacers are difficult for the etchant to reach under certain circumstances.

The invention is explained in more detail below with reference to the figures of the drawings and on the basis of a plurality of exemplary embodiments. In the drawings:

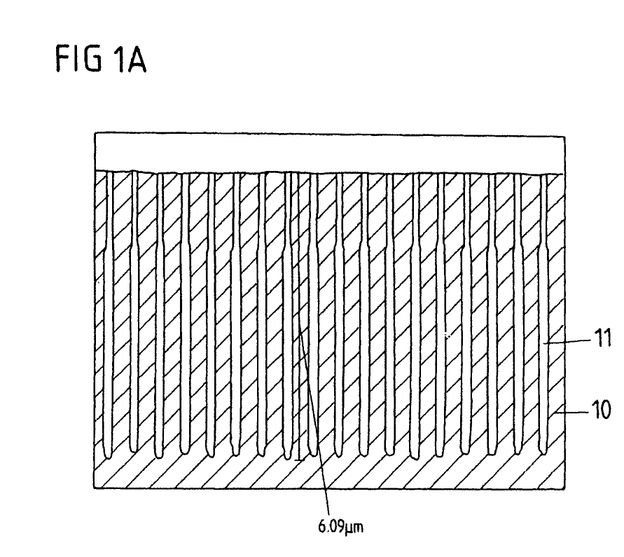

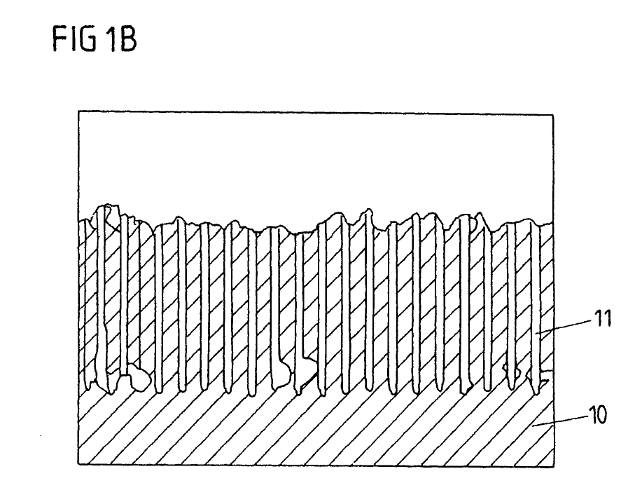

FIGS. 1A, B illustrates sectional views through a substrate which has been treated using a known process sequence in a point-of-use tank (FIG. 1A) and in a bench tool (FIG. 1B);

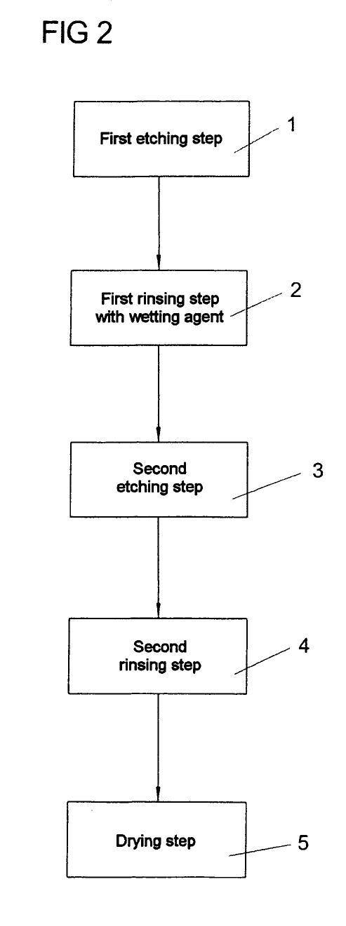

FIG. 2 shows a flow diagram of an embodiment of the process according to the invention;

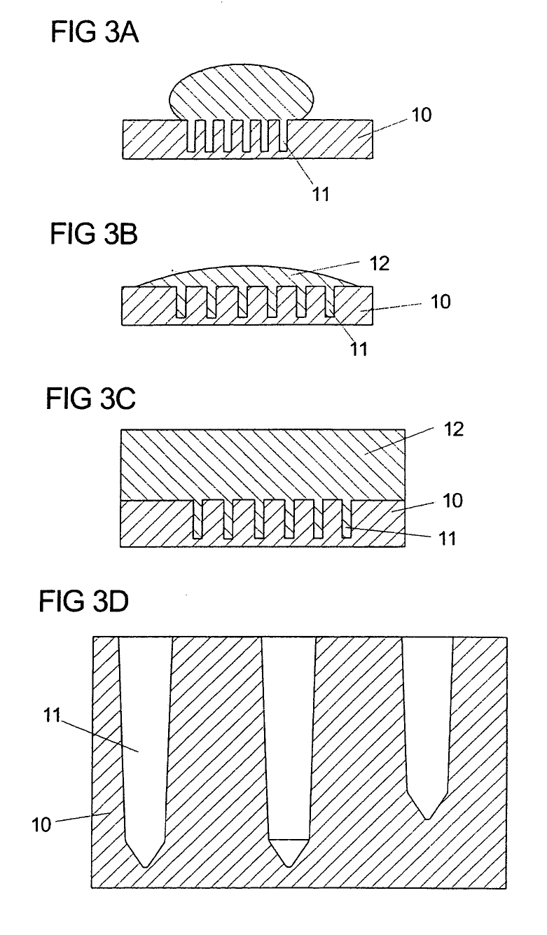

FIGS. 3A,B,C,D diagrammatically depict the effect of one embodiment of the process according to the invention.

FIGS. 1A, 1B illustrate the result of the identical sequence of process steps in the etching of a silicon wafer as substrate 10, on the one hand in a point-of-use tank process (FIG. 1A), and on the other hand for a bench tool process (FIG. 1B). In neither case is a wetting agent added.

The process steps are in this case: first etching step using dilute hydrofluoric acid, first rinsing step, second etching step using NH₄OH, second rinsing step and drying step. The sectional views illustrate the etching result after the drying step.

FIG. 1A reveals highly regular structures 11 (in this case bottle trenches) with a depth of 6.09 μm. The aspect ratio is in this case 44. The same sequence of process steps under identical conditions but using a bench tool results in an unusable result, as can be seen from FIG. 1B. The structures 11 produced in the second etching step are irregular. The reason for this is that after the first etching step using hydrofluoric acid, the surface of the silicon wafer 10 is hydrophobic, and consequently in the second etching step the NH₄OH cannot penetrate through the surface correctly into the deep structures, which leads to the poor etching quality.

This problem is solved by an embodiment of the process according to the invention which is illustrated in FIG. 2. The first process step is an etching step 1 using dilute hydrofluoric acid to remove the oxide layer on a silicon wafer 10.

The second process step is a first rinsing step 2, in which a wetting agent (surfactant; e.g. the wetting agent Easywet) is added to the first rinsing agent, with the effect that in the second etching step 3 which follows the NH₄OH can penetrate more successfully into the deep structures. In this case, therefore, the wetting agent is used not to clean surfaces, but rather as an aid to the etching of structures.

Then, a second rinsing step 4 is carried out, followed by a drying step 5. The silicon wafer 10 which has been etched in this way can then be processed further.

It is important that in this case the wetting agent is not used to clean the surface, but rather forms part of an etching process.

FIGS. 3A, B, C, D illustrate the effect of one embodiment of the process according to the invention.

After the first etching step 1, the surface of the silicon wafer 10 is hydrophobic (FIG. 3A), so that an aqueous solution cannot penetrate into structures. This is symbolized by the drop on the silicon wafer. The first rinsing step 2, in which according to the invention a wetting agent is added to the first rinsing agent 12, reduces the surface tension of an aqueous solution (FIG. 3B), so that in the second etching step NH₄OH can penetrate into the structures 11 more successfully (FIG. 3C).

FIG. 3D illustrates the true etching result on the basis of a detail of a trench. By comparison with FIG. 1B, it is clear that in this case an anisotropic etch has been achieved.

Although the process is described here in connection with trench structures, it can also be applied to structures which protrude from the surface of the silicon wafer (e.g. ridges).

The execution of the invention is not restricted to the preferred exemplary embodiments described above. Rather, numerous variants which make use of the process according to the invention even in embodiments of fundamentally different configuration are conceivable.

List of Reference Symbols

1 First etching step
2 First rinsing step with wetting agent
3 Second etching step
4 Second rinsing step
5 Drying step
10 Substrate
11 Structure in the substrate

1. A process for etching at least one substrate, comprising at least one silicon wafer for the fabrication of DRAM memory chips, in wherein
at least one substrate for a first etching is arranged for a predetermined time in a first vessel containing a first etchant, then
at least one substrates, for a first rinsing is arranged for a predetermined time in a second vessel containing a first rinsing agent, the first rinsing agent containing at least one wetting agent, and then
at least one substrate, for a second etching is arranged for a predetermined time in a third vessel containing a second etchant.

2. The process according to claim 1, wherein for at least one substrates, after the second etching a second rinsing step is carried out using a second rinsing agent in a fourth vessel.

3. The process according to claim 2, wherein for at least one substrates a drying is carried out after the second rinsing step.

4. The process according to claim 1, wherein the first etchant includes a hydrofluoric acid fraction.

5. The Process according to claim 1, wherein the second etchant includes an ammonia water (NH₄OH) fraction.

6. The process according to claim 5, wherein the first rinsing agent contains the wetting agent in a concentration in the range from 0.01 to 0.1% by weight.

7. The process according to claim 1, wherein in the second etching at least one structure with an aspect ratio in the range from 10 to 50 is introduced into the substrate.

8. The process according to claim 7, wherein the structure comprises at least one deep trench structure for a DRAM memory cell.

9. The process according to claim 1, wherein in the second etching step at least one structure with an aspect ratio of greater than 50 is introduced into the substrate.

10. A method of etching a substrate comprising:
arranging the substrate in a first vessel containing a first etchant;
performing a first etching of the substrate using the first etchant in the first vessel;
arranging the substrate in a second vessel containing a first rinsing agent comprising at least one wetting agent;
performing a first rinsing of the substrate with the first rinsing agent in the second vessel for a first predetermined time period;
arranging the substrate in a third vessel containing a second etchant; and
performing a second etching of the substrate using the second etchant in the third vessel for a second predetermined period of time.

11. The method of claim 10, wherein the substrate comprises a silicon semiconductor substrate.

12. The method of claim 11, wherein the silicon substrate are employed in a fabrication of DRAM memory chips.

13. The method of claim 10, further comprising performing a second rinsing of the substrate using a second rinsing agent in a fourth vessel.

14. The method of claim 13, further comprising drying the substrate after the second rinsing.

15. The method of claim 10, wherein the first etchant comprises a hydrofluoric acid fraction.

16. The method of claim 10, wherein the second etchant comprises an ammonia water (NH₄OH) fraction.

17. The method of claim 10, wherein the first rinsing agent contains the wetting agent in a concentration in the range from about 0.01% to about 0.1% by weight.

18. The process according to claim 10, wherein the second etching results in at least one structure formed within the substrate comprising an aspect ratio in the range of about 10 to about 50, wherein the at least one structure comprises at least one deep trench structure associated with a DRAM memory cell.

19. The process according to claim 10, wherein the second etching results in at least one structure formed within the substrate comprising an aspect ratio of greater than about 50.

20. The process according to claim 10, wherein the second etching results in at least one structure formed within the substrate comprising an aspect ratio in the range of about 10 to about 80.
